(19) United States
(12) Patent Application Publication
(10) Pub. No.: US 2025/0301750 A1
(43) Pub. Date: Sep. 25, 2025

(54) SEMICONDUCTOR DEVICES AND METHODS OF MANUFACTURING SAME

(71) Applicant: Infineon Technologies Austria AG, Villach (AT)

(72) Inventors: Alessandro Ferrara, Villach (AT); Stefan Tegan, Dresden (DE); David Laforet, Villach (AT); Syed Sarwar Imam, Villach (AT)

(21) Appl. No.: 19/075,086

(22) Filed: Mar. 10, 2025

(30) Foreign Application Priority Data
Mar. 25, 2024 (DE) 102024202836.3

(51) Int. Cl. H10D 64/00; H10D 30/01; H10D 30/66; H10D 62/17; H10D 62/60; H10D 64/27

(52) U.S. Cl. CPC H10D 64/117; H10D 30/0297; H10D 30/668; H10D 62/393; H10D 62/60; H10D 64/518

(57) ABSTRACT

A semiconductor device includes a semiconductor body having a first major surface. A trench formed in the semiconductor body extends from the first major surface into the semiconductor body along a first direction, and includes a field dielectric positioned between a field electrode and the semiconductor body. A thickness of the field dielectric increases along the first direction from a first thickness at a first distance from the first major surface to a second thickness at a second distance from the first major surface. A difference between the second and first distances along the first direction is at most 20% of a total height of the field electrode. The second thickness is at least 1.1 times the first thickness. A drift region has a doping profile along the first direction, with a slope that changes along the first direction between the first and second distances from the first major surface.

### BACKGROUND

Transistor devices used in power electronic applications are often fabricated with silicon (Si) semiconductor materials. Common transistor devices for power applications include Si CoolMOS®, Si Power MOSFETs and Si Insulated Gate Bipolar Transistors (IGBTs).

A transistor device for power applications may be based on the charge compensation principle and may include an active cell field including a plurality of trenches, each including a field electrode for charge compensation. In some designs, the trenches and the mesas that are formed between adjacent trenches each have an elongate striped structure. In some other designs, the trenches and field electrodes each have a columnar, needle-like shape.

Further improvements would be desirable to further improve the performance of transistor devices, for example by reducing the on-state resistance RDS(on)·Area or by improving other figures of merits, such as Rds(on)·Qg and Rds(on)·Qgd.

### SUMMARY

According to an embodiment, a semiconductor device may comprise a semiconductor body having a first major surface. A trench may be formed in the semiconductor body. The trench may extend from the first major surface into the semiconductor body along a first direction. The trench may comprise a field electrode and a field dielectric positioned between the field electrode and the semiconductor body. A thickness of the field dielectric may increase along the first direction from a first thickness at a first distance from the first major surface to a second thickness at a second distance from the first major surface. A difference between the second distance and the first distance along the first direction may be at most 20% of a total height of the field electrode. The second thickness may be at least 1.1 times the first thickness. The semiconductor body may comprise a drift region. The drift region may comprise a doping profile along the first direction. A slope of the doping profile may change along the first direction between the first distance and the second distance from the first major surface.

According to an embodiment, a method for fabricating a semiconductor device having semiconductor body with a first major surface may comprise growing a first part of a drift region of the semiconductor body over a substrate of the semiconductor body for a first period of time. Growing the first part may comprise changing a concentration of dopants over the first period of time with a first rate. The method may further comprise growing a second part of the drift region of the semiconductor body over the first part of the drift region for a second period of time. Growing the second part may comprise changing a concentration of dopants over the second period of time with a second rate, the second rate being greater than the first rate. The method may further comprise forming a trench in the semiconductor body. The trench may extend from the first major surface into the semiconductor body along a first direction. The method may further comprise forming a field dielectric in the trench. A thickness of the field dielectric may increase along the first direction from a first thickness at a first distance from the first major surface to a second thickness at a second distance from the first major surface. The first distance may be adjacent to the second part of the drift region. The second distance may be adjacent to the first part of the drift region. The second thickness may be at least 1.1 times the first thickness.

According to an embodiment, a method for fabricating a transistor device having a semiconductor body with a first major surface may comprise implanting dopants into a first part of a drift region of the semiconductor body such that a doping profile in the first part of the drift region comprises at least one first slope. The method may further comprise implanting dopants into a second part of the drift region positioned over the first part of the drift region such that a doping profile in the second part of the drift region comprises at least one second slope. The at least one first slope may be smaller than the at least one second slope. The method may further comprise forming a trench in the semiconductor body. The trench may extend from the first major surface into the semiconductor body along a first direction. The method may further comprise forming a field dielectric in the trench. A thickness of the field dielectric may increase along the first direction from a first thickness at a first distance from the first major surface to a second thickness at a second distance from the first major surface, wherein the first distance is adjacent to the second part of the drift region, and wherein the second distance is adjacent to the first part of the drift region, wherein the second thickness is at least 1.1 times the first thickness.

According to an embodiment, a semiconductor device comprises a semiconductor body having a first major surface. The semiconductor may further comprise a trench formed in the semiconductor body. The trench may extend from the first major surface into the semiconductor body along a first direction. The trench may comprise a field electrode and a field dielectric positioned between the field electrode and the semiconductor body. The field dielectric may comprise a first thickness over a first height h₁ of the field electrode and a second thickness over a second height h₂ of the field electrode. The field electrode may comprise a total height h_{fp}, where 0.1<h₁/h_{fp}<0.8, 0.1<h₂/h_{fp}<0.8, and (h₁+h₂)/h_{fp}<0.9. The semiconductor body may comprise a drift region. The drift region may comprise a doping profile along the first direction. A slope of the doping profile may change along the first direction between the first distance and the second distance from the first major surface.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1A illustrates a partial cross-sectional view of a semiconductor device, according to embodiments of the present disclosure.

FIG. 1B illustrates a partial cross-sectional view of a semiconductor device, according to embodiments of the present disclosure.

FIG. 1C illustrates a partial top plan view of the semiconductor device shown in FIGS. 1A-1B.

FIG. 2A illustrates a partial cross-sectional view of another embodiment of a semiconductor device.

FIG. 2B illustrates a partial cross-sectional view of yet another embodiment of a semiconductor device.

FIG. 2C illustrates a partial top plan view of the semiconductor device shown in FIGS. 2A-2B.

FIG. 3 illustrates a partial cross-sectional view of another embodiment of a semiconductor device.

FIGS. 4A-4C illustrate different embodiments of aspects of the semiconductor device illustrated in FIGS. 1A-1C, 2A-2C, and 3.

FIG. 5 illustrates an embodiment of producing the semiconductor devices illustrated in FIGS. 1A-1C, 2A-2C, and 3A-3C.

FIG. 6 illustrates another embodiment of producing the semiconductor devices illustrated in in FIGS. 1A-1C, 2A-2C, and 3A-3C.

### DETAILED DESCRIPTION

In the following detailed description, reference is made to the accompanying drawings, which form a part hereof, and in which is shown by way of illustration specific embodiments in which the invention may be practiced. In this regard, directional terminology, such as “top”, “bottom”, “front”, “back”, “leading”, “trailing”, etc., is used with reference to the orientation of the figure(s) being described. Because components of the embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, thereof, is not to be taken in a limiting sense, and the scope of the present invention is defined by the appended claims.

A number of exemplary embodiments will be explained below. In this case, identical structural features are identified by identical or similar reference symbols in the figures. In the context of the present description, “lateral” or “lateral direction” should be understood to mean a direction or extent that runs generally parallel to the lateral extent of a semiconductor material or semiconductor carrier. The lateral direction thus extends generally parallel to these surfaces or sides. In contrast thereto, the term “vertical” or “vertical direction” is understood to mean a direction that runs generally perpendicular to these surfaces or sides and thus to the lateral direction. The vertical direction therefore runs in the thickness direction of the semiconductor material or semiconductor carrier.

As employed in this specification, when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present.

As employed in this specification, when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As used herein, various device types and/or doped semiconductor regions may be identified as being of n type or p type, but this is merely for convenience of description and not intended to be limiting, and such identification may be replaced by the more general description of being of a “first conductivity type” or a “second, opposite conductivity type” where the first type may be either n or p type and the second type then is either p or n type.

The Figures illustrate relative doping concentrations by indicating “−” or “+” next to the doping type “n” or “p”. For example, “n-” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations.

According to embodiments, the semiconductor device is a transistor device (such as a power transistor device) and may be a MOSFET (Metal Oxide Semiconductor Field Effect Transistor) device, a superjunction transistor device or an insulated gate bipolar transistor (IGBT) device. The transistor device may be a vertical transistor device with a drift path that extends substantially perpendicularly to the major surfaces of the device.

The regions and terminals of the transistor device are referred to herein as source, drain and gate regions/terminals. As used herein, these terms also may encompass the functionally equivalent regions/terminals of other types of transistor devices, such as an insulated gate bipolar transistor (IGBT). For example, as used herein, the term “source” region/terminal may encompass not only a source region/terminal of a MOSFET device and of a superjunction device but also an emitter region/terminal of an insulator gate bipolar transistor (IGBT) device, the term “drain” region/terminal may encompass not only a drain of a MOSFET device or of a superjunction device but also a collector of an insulator gate bipolar transistor (IGBT) device and a collector of a BJT device, and the term “gate” region/terminal may encompass not only a gate of a MOSFET device or of a superjunction device but also a gate of an insulator gate bipolar transistor (IGBT) device.

Some embodiments are described next with reference to the Figures. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

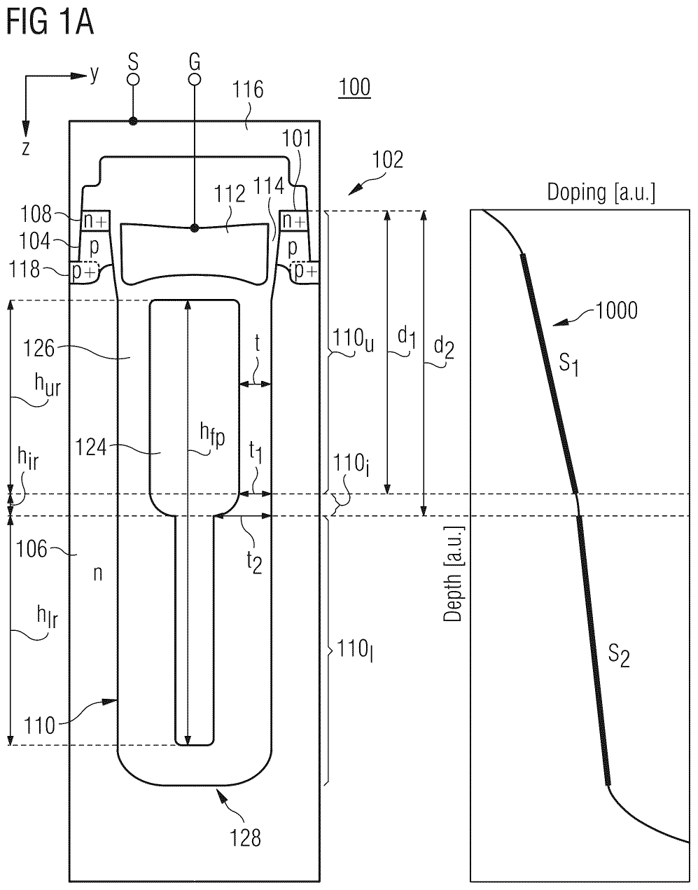

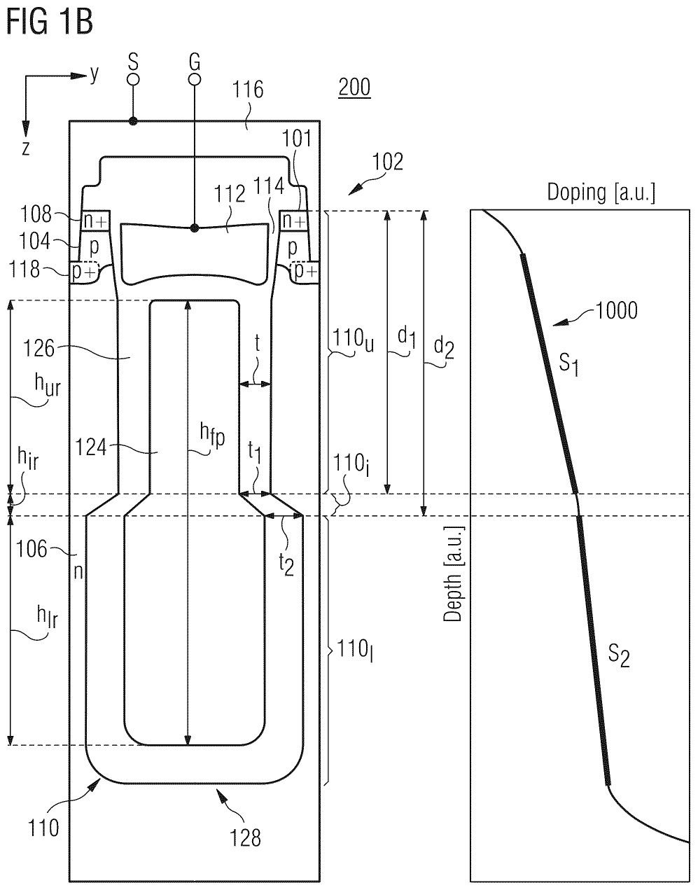

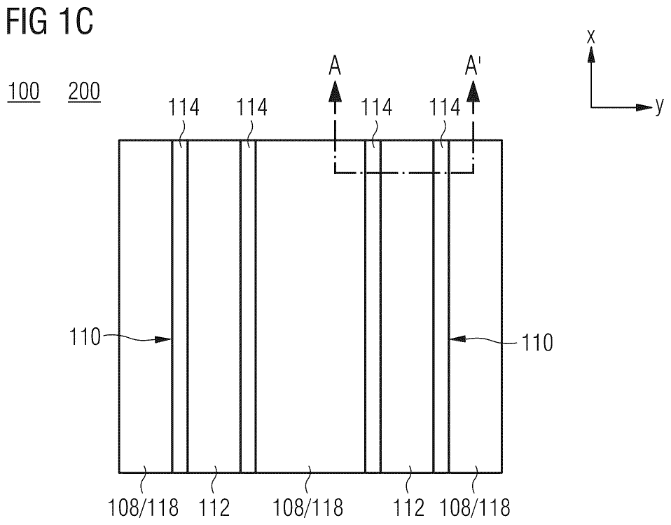

FIG. 1A illustrates a partial cross-sectional view of a semiconductor device 100 according to embodiments of the present disclosure. FIG. 1B illustrates a partial cross-sectional view of another embodiment of a semiconductor device 200. FIG. 1C illustrates a partial top plan view of the vertical power semiconductor transistor devices 100, 200 shown in FIG. 1A-B. The partial cross-sectional view in FIGS. 1A-1B is taken along the line labeled A-A′ in FIG. 1C.

The semiconductor device 100 illustrated in FIG. 1A differs from the semiconductor device 200 illustrated in FIG. 1B only with regard to the shape of the trench 110, the shape of the field electrode 124, and the shape of the field dielectric 126. Optionally, also the shape of the gate electrode 112 and the gate dielectric 114 may be different between the semiconductor device 100 illustrated in FIG. 1A and the semiconductor device 200 illustrated in FIG. 1B (not shown).

The semiconductor device 100, 200 comprises a semiconductor body 102. The semiconductor body may comprise (e.g., may be made of) a semiconductor material, such as silicon or silicon carbide. The semiconductor body 102 may comprise a drain region (not shown in FIGS. 1A and 1B) of a first conductivity type, a body region 104 of a second conductivity type opposite the first conductivity, a drift region 106 of the first conductivity type and which separates the body region 104 from the drain region, and a source region 108 of the first conductivity type and which is separated from the drift region 106 by the body region 104. The first conductivity type is n-type and the second conductivity type is p-type in the case of an n-channel device. In the case of a p-channel device, the first conductivity type is p-type and the second conductivity type is n-type. For ease of illustration only, the first conductivity type is labeled n-type (e.g. ‘n’, ‘n+’) and the second conductivity type is labeled p-type (e.g. ‘p’, ‘p+’) FIGS. 1A-1B. The labels ‘n’, ‘n+’, ‘p’, and ‘p+’ in FIGS. 1A-1B indicate general relative dopant concentration relationships among different regions of the same doping type and are not intended to be limiting with respect to particular doping concentrations, ranges or profiles. For example, a region labeled ‘n+’ indicates that the region is doped more heavily that a region labeled ‘n’.

A trench 110 extends through the source region 108 and the body region 104 and into the drift region 106. The trench 110 includes a gate electrode 112 which is insulated from the surrounding semiconductor material by a gate dielectric 114. The gate electrode 112 may extend lengthwise (direction ‘x’ in Figure Ref. FIG. 1C) in a stripe-like manner and/or form part of a grid. Directions ‘x’ and ‘y’ in Figure Ref. FIGS. 1A-1C are lateral (horizontal) directions which run perpendicular to one another and parallel to a first major surface 101 of the semiconductor device 100, 200, whereas direction ‘z’ is a vertical direction which runs depth-wise into the semiconductor device 100, 200 and perpendicular to the first major surface 101 of the device 100.

The semiconductor device 100, 200 may also include a source electrode 116 for providing a source potential (‘S’) to the body region 104 and the source region 108 of the semiconductor device 100, 200. The body region 104 may include a heavily doped body contact region 118 to ensure an Ohmic contact between the source electrode 116 and the body region 104. A drain electrode (not shown) at the opposite side of the semiconductor device 100 provides a drain potential to the heavily doped drain region (not shown) of the semiconductor device 100. A conductive channel region may arise in the body region 104 under appropriate biasing of the source electrode 116, drain electrode and gate electrode 112 of the device 100.

According to the embodiments illustrated in FIGS. 1A-1C, the semiconductor device 100, 200 also includes a field electrode 124 disposed in the same trench 110 as the gate electrode 112. The field electrode 124 is insulated from the gate electrode 112 and the surrounding semiconductor material by a field dielectric 126 which may be of the same material as the gate dielectric 114 (e.g. an oxide or a nitride) or a different insulative material. The field electrode 124 may be biased at the source (S) potential, another potential, or floating.

Semiconductor device 100, 200 comprises semiconductor body 102 having a first major surface 101. Trench 110 is formed in the semiconductor body 102. The trench 110 extends from the first major surface 101 into the semiconductor body 102 along a first direction z. The trench 110 comprises a field electrode 124 and a field dielectric 126 positioned between the field electrode 124 and the semiconductor body 102.

The trench 110 may comprise an upper region 110ᵤ, a lower region 110ₗ and an intermediate region 110ᵢ positioned between the upper region 110ᵤ and the lower region 110₁. The upper region 110ᵤ may be located closer to the first major surface 110 as compared to the intermediate region 110ᵢ and the lower region 110ₗ. The intermediate region 110 may be positioned between a first distance d₁ and a second distance d₂ (e.g., where the thickness of the field dielectric 126 changes from the first thickness t₁ to the second thickness t₂). The distances d₁ and d₂ are measured from the first major surface 101 of the semiconductor body, whereas d₂ may be larger as d₁. In other words, d₂ may reach deeper into the semiconductor body 102 as d₁. The field electrode 124 may extend from the upper region 110ᵤ into the lower region 110ₗ of the trench (110).

A thickness t of the field dielectric 126 increases along the first direction z from a first thickness t₁ at the first distance d₁ from the first major surface 101 to a second thickness t₂ at the second distance d₂ from the first major surface 101. This may occur in the intermediate region 110ᵢ of trench 110. In one embodiment, a difference d between the second distance d₂ and the first distance d₁ along the first direction z is at most 20% of a total height h_{fp} of the field electrode 124, and the second thickness t₂ is at least 1.1 times the first thickness t₁. In other examples, a difference d between the second distance d₂ and the first distance d₁ along the first direction z is at most 15% of a total height h_{fp} of the field electrode 124, and the second thickness t₂ is at least 1.2 times the first thickness t₁. In yet other examples, a difference d between the second distance d₂ and the first distance d₁ along the first direction z is at most 10% of a total height h_{fp} of the field electrode 124, and the second thickness t₂ is at least 1.15 times the first thickness t₁.

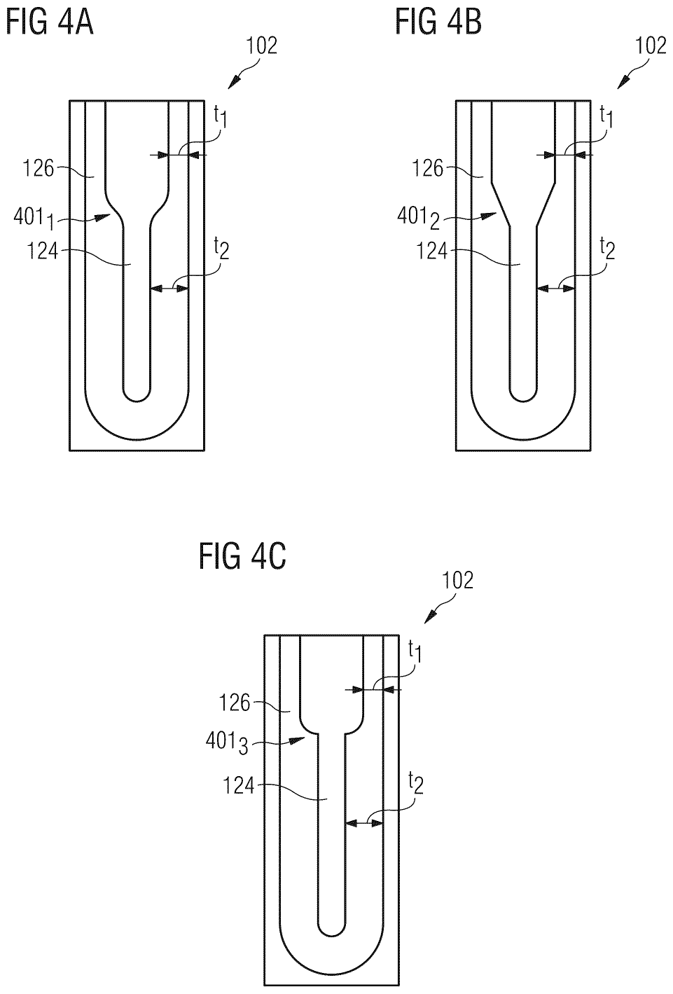

In other words, the field dielectric 126 may comprise a section, where the thickness t of the field dielectric 126 changes from the first thickness t₁ at the first distance d₁ to the second thickness t₂ at the second distance d₂. In this section, the field dielectric 126 may have a step-like shape, as illustrated in FIG. 1A. The field dielectric may also have different shapes in this section, as illustrated with regard to FIGS. 4A-4C further below.

The semiconductor body 102 may further comprise a drift region 106. The drift region 106 comprises a doping profile 1000 along the first direction z. A slope of the doping profile 1000 changes along the first direction z between the first distance d₁ and the second distance d₂ from the first major surface 101. In other words, the slope of doping profile may change over the same distance (between d₁ and d₂ from the first major surface 101) where the thickness of the field dielectric 126 changes from the first thickness t₁ to the second thickness t₂.

According to embodiments, along the first direction z, a height hᵤᵣ of the field electrode 124 in the upper region 110ᵢ is more than 25% of the total height h_{fp} of the field electrode 124, and a height hₗᵣ of the field electrode 124 in the lower region 110ᵢ is more than 25% of the total height h_{fp} of the field electrode 124.

The field electrode 124 may comprise a height hᵢᵣ in the intermediate region 110ᵢ of trench 110 (measured along the z direction). The field dielectric 126 may change its thickness t from the first thickness t₁ to the second thickness t₂ adjacent to the field electrode 124 in the intermediate region 110ᵢ of trench 110. In some embodiments, the section of the field dielectric 126 where the thickness t changes from the first thickness t₁ to the second thickness t₂ (such as the section of the field electrode 124 that has the height hᵢᵣ) may be located in trench 110 such that 10% or 20% of a total height h_{fp} of the field electrode 124 are located above the section of the field dielectric 126 where the thickness t changes from the first thickness t₁ to the second thickness t₂. In other embodiments, the section of the field dielectric 126 where the thickness t changes from the first thickness t₁ to the second thickness t₂ (such as the section of the field electrode 124 that has the height hᵢᵣ) may be located in trench 110 such that 80% or 70% of a total height h_{fp} of the field electrode 124 are located above the section of the field dielectric 126 where the thickness t changes from the first thickness t₁ to the second thickness t₂. In one embodiment, the section of the field dielectric 126 where the thickness t changes from the first thickness t₁ to the second thickness t₂ (such as the section of the field electrode 124 that has the height hᵢᵣ) may be located in trench 110 such that a height hₗᵣ of the field electrode 124 in the lower region 110ᵢ and a height hᵤᵣ of the field electrode 124 in the upper region 110ᵢ are substantially equal (when taking processing variations into account, such as +/−1 or 2%). According to some embodiments the field dielectric 126 comprises the first thickness t₁ substantially over the entire height hᵤᵣ of the field electrode 124 and the second thickness t₂ substantially over the entire height hₗᵣ of the field electrode 124 (only varying with respect to process variations). In this case, 0.1<h1/h_{fp}<0.8, 0.1<h2/h_{fp}<0.8, and (h1+h2)/h_{fp}<0.9 may hold.

Generally speaking, the second thickness t₂ of the field dielectric 126 may depend on a voltage class of the semiconductor device 100, 200. For example, t₂ may be 5 nm/V times Voltage Class +/−50%. The first thickness t₁ may also depend on the voltage class of the semiconductor device 100, 200 and in addition to that to on the height hᵤᵣ of the field electrode 124 in the upper region 110ᵤᵣ as well as on the total height h_{fp} of the field electrode 124. For example, t₁ may be greater to or equal than 0.5 times 5 nm/V times Voltage Class times (hᵤᵣ/h_{fp}). This may reflect the fact that as the transition from the first thickness t₁ to the second thickness t₂ gets deeper, t₁ may need to get thicker due to an increase in the electric field.

Referring to FIG. 1A, the thickness of the field electrode 124 decreases along the first direction z from a first thickness of the field electrode 124 at the first distance d₁ to a second thickness of the field electrode 124 at the second distance d₂. Typical ratios of the first thickness w₂ of the field electrode at the first distance d₁ versus the second thickness w₂ of the field electrode at the second distance d₂ may be 1.5≤w₁/w₂≤4. In one embodiment, where the voltage class of semiconductor device 100, 200 is 60V, the ratio w₁/w₂ may be around 2, such as 1.75≤w₁/w₂≤2.25.

Referring to FIG. 1B, the thickness of the field electrode 124 increases along the first direction z from a first thickness of the field electrode 124 at the first distance d₁ to a second thickness of the field electrode 124 at the second distance d₂. A typical relationship between the first thickness w₁ of the field electrode at the first distance d₁ and the second thickness w₂ of the field electrode at the second distance d₂ may be 1.1 w₁≤w₂. In some embodiments (not shown in FIG. 1B) a thickness of the field electrode 124 may remain the same between the first distance d₁ and the second distance d₂. Referring to FIG. 1C, it can be seen that for both embodiments shown in FIGS. 1A-1B the trench 110 may be elongated along a second direction (x), and the trench 110 may further comprises a gate electrode 112 positioned above the field electrode 124.

As discussed above, a doping profile 1000 of the semiconductor body along the first direction z may have a slope that changes along the first direction z between the first distance d₁ and the second distance d₂ from the first major surface 101. For example, the slope of doping profile may change over the same distance (between d₁ and d₂ from the first major surface 101) where the thickness of the field dielectric 126 changes from the first thickness t₁ to the second thickness t₂. In some embodiments, the slope of the doping profile 1000 changes between the first distance d₁ and the second distance d₂ approximately proportional to a ratio between the first thickness t₁ of the field dielectric 126 over the second thickness t₂ of the field dielectric 126.

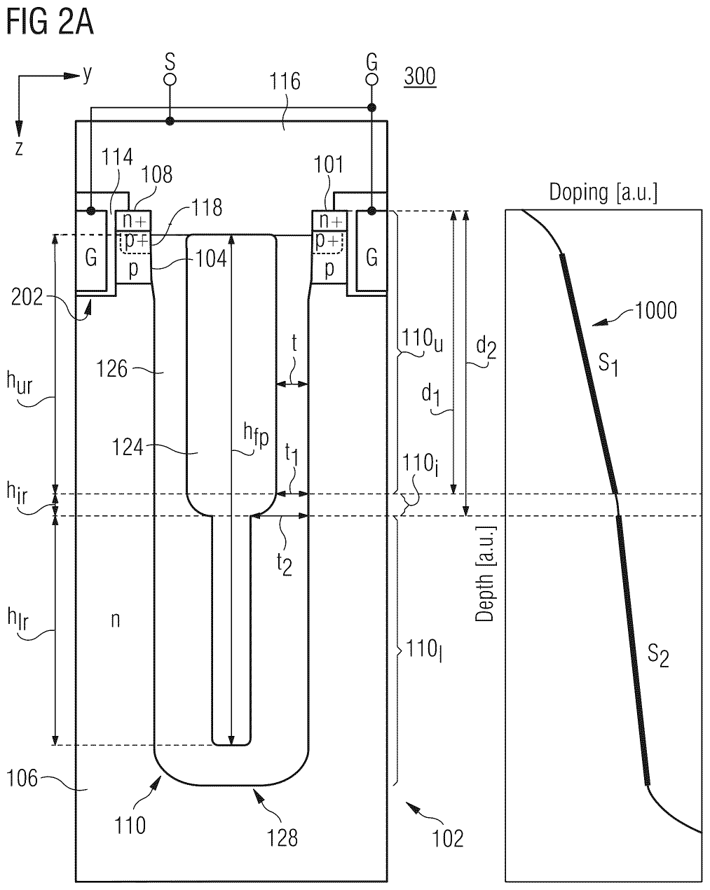

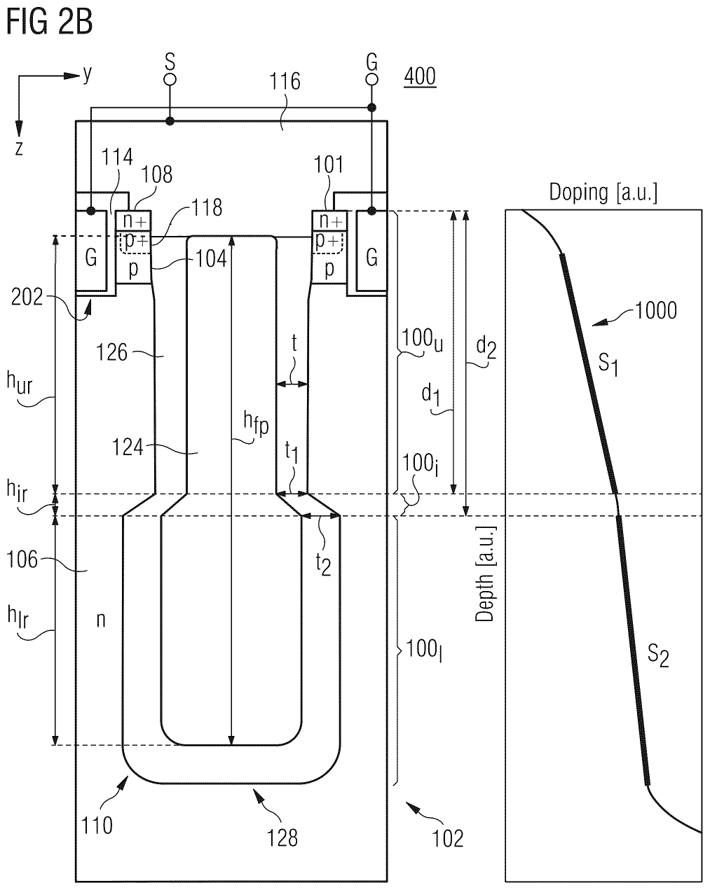

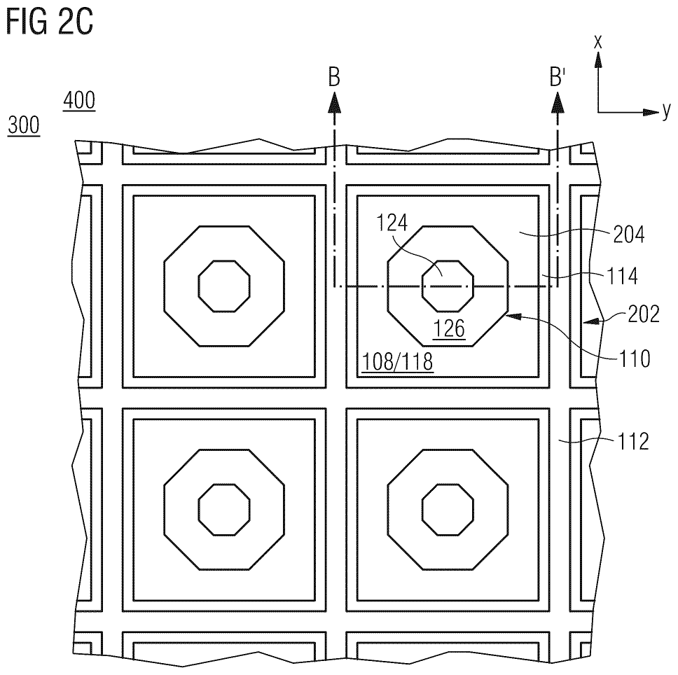

FIG. 2A illustrates a partial cross-sectional view of another embodiment of a semiconductor device 300. FIG. 2B illustrates a partial cross-sectional view of yet another embodiment of a semiconductor device 400. FIG. 2C illustrates a partial top plan view of the semiconductor devices 300, 400 shown in FIGS. 2A-2B. The partial cross-sectional views in FIGS. 2A-2B are taken along the line labeled B-B′ in Figure Ref. FIG. 2C.

The semiconductor device 300 illustrated in FIG. 2A differs from the semiconductor device 400 illustrated in FIG. 2B only with regard to the shape of the trench 110, the shape of the field electrode 124, and the shape of the field dielectric 126. Same reference signs in FIGS. 2A-2C and in FIGS. 1A-1C relate to same or similar components and will not be described again with regard to FIGS. 2A-2C, but reference to the description that was made above with regard to FIGS. 1A-1C is made for brevity.

The embodiments illustrated FIGS. 2A-2C are similar to the embodiments illustrated in FIGS. 1A-1C. Different, however, the field electrode 124 is in a different trench 110 than the gate electrode 112 which is placed in trench 202 and the field electrode 124 has a columnar shape (such as a needle-shape) in a lengthwise extension (direction ‘z’ in FIGS. 2A-2C) of the field electrode 124. The term “columnar-shaped” or “needle-shaped” as used herein describes an electrode structure having a small or narrow circumference or width in proportion to its height/depth in a semiconductor material, as opposed to a stripe-shaped electrode structure which is longer than it is deeper as shown in FIGS. 1A-1C. Of course, the width of trench 110 may vary along the vertical direction (z) or the lateral directions (x, y), but each width is smaller than the height/depth of the trench 110.

In the embodiment illustrated in FIG. 2C, the columnar field electrode trenches 110 are illustrated as having an octagonal lateral form in top view. However, the columnar trench 110 may have other lateral forms in top view. For example, the columnar or needle trench 110 may have a circular, square or a hexagonal shape in top view. In addition, FIG. 2C illustrates the trenches 110 being arranged in a square pattern, with trenches 110 being arranged at corners of the square. Other patterns are also contemplated by the present disclosure, such as hexagonal patterns or triangular patterns. In cross-section, the columnar trenches 110 may have the same structure irrespective of the pattern of the array or the lateral shape of the columnar trench 110 and columnar field electrode 124.

The gate trenches 202 may be formed as a grid, e.g., as shown in FIG. 2C or as stripes, e.g., as shown in FIG. 1C. In either case, the use of columnar-shaped field-plate trenches 110 may be beneficial as the remaining silicon mesa area 204 which surrounds each field electrode trench 110 and defined by the adjacent gate trenches 202 may be larger compared to the trench stripe structures shown in FIG. 1C, enabling a lower on-resistance.

Referring to FIG. 2A (which is similar to FIG. 1A), the thickness of the field electrode 124 decreases along the first direction z from a first thickness of the field electrode 124 at the first distance d₁ to a second thickness of the field electrode 124 at the second distance d₂.

Referring to FIG. 2B (which is similar to FIG. 1B), the thickness of the field electrode 124 increases along the first direction z from a first thickness of the field electrode 124 at the first distance d₁ to a second thickness of the field electrode 124 at the second distance d₂. In some embodiments (not shown in FIG. 2B) a thickness of the field electrode 124 may remain the same between the first distance d₁ and the second distance d₂.

Yet again, a doping profile 1000 of the semiconductor body 102 along the first direction z may have a slope that changes along the first direction z between the first distance d₁ and the second distance d₂ from the first major surface 101. For example, the slope of doping profile may change over the same distance (between d₁ and d₂ from the first major surface 101) where the thickness of the field dielectric 126 changes from the first thickness t₁ to the second thickness t₂. In some embodiments, the slope of the doping profile 1000 changes between the first distance d₁ and the second distance d₂ approximately proportional to a ratio between the first thickness t₁ of the field dielectric 126 over the second thickness t₂ of the field dielectric 126.

In FIGS. 1A-1C and 2A-2C, doping profile 1000 is shown as a function of the depth (along direction z) of the semiconductor body 101. The doping profile 1000 may have at least a first slope s₁ in the drift region 106 that lies adjacent a region of the field dielectric 126 that is located above the region where the thickness t of the field dielectric 126 changes from the first thickness t₁ to the second thickness t₂. In other words, the doping profile 1000 may have at least a first slope s₁ in the region of the drift region 106 that has a smaller distance from the first major surface 101 than the first distance d₁ when measured along the z-direction. The doping profile 1000 may have at least a second slope s₂ in the drift region 106 that lies adjacent a region of the field dielectric 126 that is located below the region where the thickness t of the field dielectric 126 changes from the first thickness t₁ to the second thickness t₂. In other words, the doping profile 1000 may have at least a second slope s₂ in the region of the drift region 106 that has a larger distance from the first major surface 101 than the second distance d₂ when measured along the z-direction. In some examples, a ratio between the first slope s₁ and the second slope s₂ may be approximately proportional to a ratio between the second thickness t₂ and the first thickness t₁. This, however, should not be construed limiting and other choices for the slopes s₁ and s₂ are contemplated by the present disclosure. As can be seen in FIGS. 1A-1B and FIGS. 2A-2B, the slope of the doping profile 1000 changes between the first distance d₁ and the second distance d₂. In some embodiments, the second slope s₂ is smaller than the first slope s₁.

In some embodiments, the region of the drift region 106 that has a smaller distance from the first major surface 101 than the first distance d₁ (when measured along the z-direction) has a generally linearly graded first doping profile (such as with a generally constant slope s₁), and, the region of the drift region 106 that has a larger distance from the first major surface 101 than the second distance d₂ (when measured along the z-direction) has a generally linearly graded second doping profile (such as with a generally constant slope s₂). The phrase “generally linearly graded” or “generally constant slope” as used herein means, in a general manner, a rate of inclination that resembles a straight line. As such, both the first doping profile and the second doping profile of the drift region 106 may have one or more areas of localized nonlinearity due to process variation, material imperfections, etc., but overall increases like a straight line.

The absolute levels of the doping profile 1000 may vary depending on the voltage class of the device 100, 200, 300, 400. For example, in the case of a 100 V device, the drift region 106 may have a doping level around the pn-junction with the body region 104 of about 1 e16 cm-3 and increase to a level of between 1e16 and 5e16 cm-3 at the first distance d₁. The doping level of the drift region 106 may only slightly increase between the first distance d₁ and the second distance d₂, e.g., such that the doping level at distance d₂ is smaller or equal to 1.2 times the doping level at distance d₁. The doping level of the drift region 106 may further increase from the second distance d₂ to a depth of trench 110 to 2e16 to 2e17 cm-3.

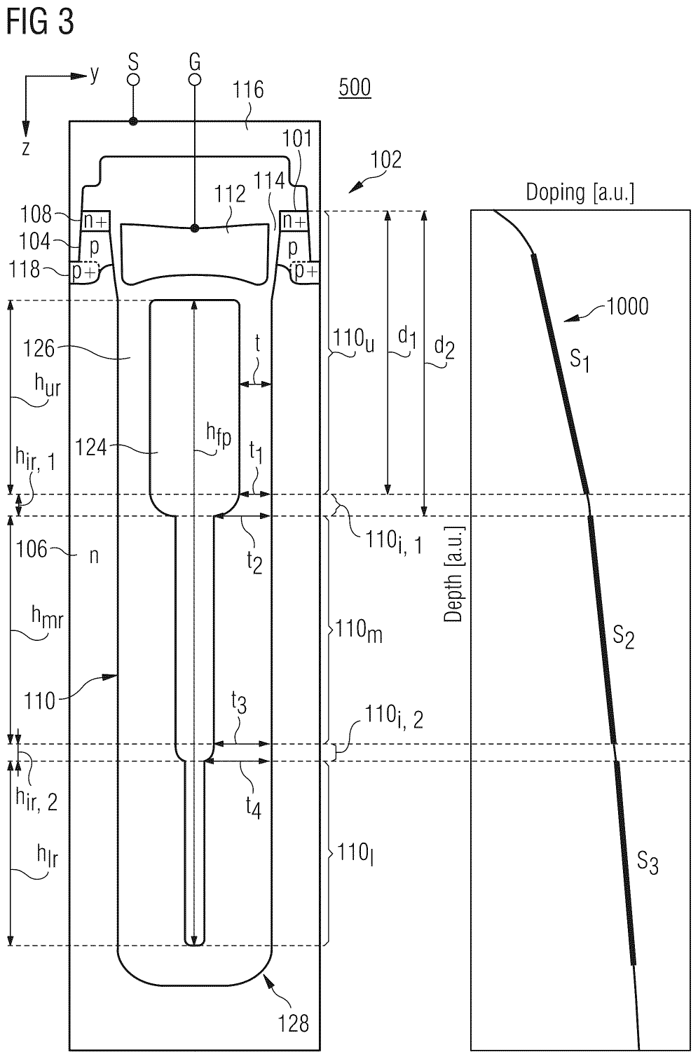

FIG. 3 illustrates another embodiment of a semiconductor device 500 according to the present disclosure. The semiconductor device 500 is similar to the semiconductor device 100 illustrated in FIG. 1A and differs in that the field dielectric 126 comprises an additional region where the thickness t of the field dielectric changes from a third thickness t₃ at a distance d₃ from the first major surface 101 to a fourth thickness t₄ at a fourth distance d₄ from the first major surface 101. It is to be understood that also the semiconductor devices 200, 300, 400 illustrated with regard to FIGS. 1B, 2A, 2B may have an additional region where the thickness t of the field dielectric changes similar to the semiconductor device shown with regard to FIG. 3. Same reference signs in FIG. 3 and in FIGS. 1A-2C relate to same or similar components and will not be described again with regard to FIG. 3, but reference to the description that was made above with regard to FIGS. 1A-2C is made for brevity.

As can be seen in FIG. 3, the semiconductor device 500 may comprise a thickness t of the field dielectric 126 which increases along the first direction z from a third thickness t₃ at a third distance d₃ from the first major surface 101 to a fourth thickness t₄ at a fourth distance d₄ from the first major surface 101. In particular, the third thickness t₃ may be equal to or greater than the second thickness t₂. The fourth distance d₄ is greater than the third distance d₃, which is greater than the second distance d₂ when measured along the z-direction. A difference d between the fourth distance d₄ and the third distance d₃ along the first direction z may be at most 20% of the total height h_{fp} of the field electrode 124. The fourth thickness t₄ may be at least 1.1 times the third thickness t₃. In other examples, a difference d between the fourth distance d₄ and the third distance d₃ along the first direction z is at most 15% of a total height h_{fp} of the field electrode 124, and the fourth thickness t₄ is at least 1.2 times the third thickness t₃. In yet other examples, a difference d between the fourth distance d₄ and the third distance d₃ along the first direction z is at most 10% of a total height h_{fp} of the field electrode 124, and the fourth thickness t₄ is at least 1.15 times the third thickness t₃.

The trench 110 may comprise an upper region 110ᵤ, a lower region 110₁, a middle region 110ₘ and first and second intermediate region 110ᵢ₁, 110ᵢ₂ positioned between the upper region 110ᵤ and the middle region 110ₘ and between the middle region 110ₘ and the lower region 110ₗ, respectively. The middle region 110ₘ may be located closer to the first major surface 110 as compared to the second intermediate region 110ᵢ₂ and the lower region 110ₗ. The first intermediate region 110ᵢ₁ may be positioned between a first distance d₁ and a second distance d₂ (e.g., where the thickness of the field dielectric 126 changes from the first thickness t₁ to the second thickness t₂). The second intermediate region 110ᵢ₂ may be positioned between a third distance d₃ and a fourth distance d₄ (e.g., where the thickness of the field dielectric 126 changes from the third thickness t₃ to the fourth thickness t₄). The distances d₁, d₂, d₃ and d₄ are measured from the first major surface 101 of the semiconductor body 102, whereas d₄ may be larger as d₃ which may be larger as d₂ which may be larger as d₁. The field electrode 124 may extend from the upper region 110ᵤ into the lower region 110ᵢ of the trench (110).

In embodiments, the field electrode 124 and/or field dielectric 124 may be arranged such that a height hᵤᵣ of the field electrode 124 in an upper region 110ᵤ of trench 110, a height hₘᵣ of the field electrode 124 in a middle region 110ₘ of trench 110, and a height hₗᵣ of the field electrode 124 in a lower region 110ᵤ of trench 110 are substantially equal (such as within +/−5%).

In other words, the field dielectric 126 may comprise at least two sections, where the thickness t of the field dielectric changes: a first section where the thickness changes from the first thickness t₁ at the first distance d₁ to the second thickness t₂ at the second distance d₂, and a second section where the thickness changes from the third thickness t₃ at the third distance d₃ to the fourth thickness t₄ at the fourth distance d₄. In the first and second sections, the field dielectric 126 may have a step-like shape, as illustrated in FIG. 3. The field dielectric 126 may also have different shapes in the first and second sections, as illustrated with regard to FIGS. 4A-4C further below.

In FIG. 3, the thickness of the field electrode 124 decreases along the first direction z from a first thickness of the field electrode 124 at the first distance d₁ to a second thickness of the field electrode 124 at the second distance d₂, and further decreases along the first direction z from a third thickness of the field electrode 124 at the third distance d₃ to a fourth thickness of the field electrode 124 at the fourth distance d₄. However, the thickness of the field electrode 124 can also increase along the first direction over the first and second sections, similar to the embodiments illustrated with reference to FIG. 1B. Likewise, the embodiments shown with regard to FIGS. 2A-2C could also have multiple sections where the thickness of the field dielectric 126 and the field electrode 124 change.

The doping profile 1000 of the semiconductor body 102 may comprise a slope that changes along the first direction z between the third distance d₃ and the fourth distance d₄ from the first major surface 101 (i.e., in the region adjacent to the trench 110 where the field dielectric 126 changes from the third thickness t₃ to the fourth thickness t₄). For example, the doping profile 1000 may have at least a second slope s₂ in the drift region 106 that lies adjacent a region of the field dielectric 126 that is located above the region where the thickness t of the field dielectric 126 changes from the third thickness t₃ to the fourth thickness t₄. The doping profile 1000 may have at least a third slope s₃ in the drift region 106 that lies adjacent a region of the field dielectric 126 that is located below the region where the thickness t of the field dielectric 126 changes from the third thickness t₃ to the fourth thickness t₄. In some examples, a ratio between the second slope s₂ and the third slope s₃ may be approximately proportional to a ratio between the fourth thickness t₄ and the third thickness t₃. This, however, should not be construed limiting and other choices for the slopes s₂ and s₃ are contemplated by the present disclosure. In some embodiments, the third slope s₃ is smaller than the second slope s₂.

The above was described with regard to two “steps” in the field dielectric 126, however, it is also contemplated that even more “steps” in the field dielectric with corresponding changes in slope of the doping profile (such as, three, four, five, six, and so on) are contemplated and encompassed by the present disclosure.

FIG. 4A illustrates an enlarged view of a portion of trench 110 including a field electrode 124 and a field dielectric 126 according to another embodiment. This embodiment of the field dielectric 126 and field electrode 124 may be used in the semiconductor devices 100, 200, 300, 400, 500 illustrated in FIGS. 1A-1C, 2A-2C, 3 in place of or as part of the field dielectric 126 and field electrode 124 shown therein. For example, the embodiments shown with regard to FIGS. 4A-4C show different shapes of the transition of the field dielectric 125 from one thickness (such as the first thickness t₁ or the third thickness t₃ discussed above) to another thickness (such as the second thickness t₂ or the fourth thickness t₄ discussed above).

Over the height of the intermediate region hᵢᵣ of the field electrode 124, the thickness of the field dielectric 126 changes from the first thickness t1 at distance d₁ from the first major surface 101 to the second thickness t2 at the second distance d₂ from the first major surface 101. In the embodiment shown with regard to FIG. 4A, the field dielectric 126 may be edgeless. In other words, the field dielectric 126 does not include a sharp abrupt change in thickness, at the second distance d₂ from the first major surface 101. Instead, the field dielectric 126 includes a curved form at the second distance d₂. The surface of the field dielectric 126 can be considered to have a concave form at the first distance d₁ and a convex form at the second distance d₂. In other embodiments, the field dielectric 126 may change substantially linearly between the first distance d₁ and the second distance d₂ from the first major surface 101, as can be seen in FIG. 4B. In yet other embodiments, the field dielectric 126 may have a “step-like” shape, as also exemplarily shown in FIGS. 1A-2C and 3 shown above, where the field dielectric may have a rather abrupt change in thickness at the second distance d₂. An abrupt change may be considered to have an angle α of approximately 90° being formed between the field dielectric 126 being located below the second distance d₂ and above the second distance d₂. While reference has been made to FIGS. 4A-C for illustrating profiles for the transition of the field dielectric 126 from one thickness to another, also other profiles are contemplated and encompassed by the present disclosure.

Described next are embodiments of producing the semiconductor devices 100, 200, 300, 400, 500 illustrated in FIGS. 1A-1C, 2A-2C, 3, and 4A-4C.

FIG. 5 illustrates an embodiment of producing the semiconductor devices 100, 200, 300, 400, 500 illustrated in illustrated in FIGS. 1A-1C, 2A-2C, 3, and 4A-4C. According to this embodiment, a first part of a drift region 106 of a semiconductor body 102 is grown 610 over a substrate of the semiconductor body for a first period of time. The step of growing 610 the first part comprises changing a concentration of dopants over the first period of time with a first rate. For example, the first part of the drift region 106 may be grown using an epitaxial growth process with the concentration of dopants present during the epitaxial growth process changing (such as decreasing) over the first period of time with the first rate. In some embodiments the first rate may be the same over the first period of time

Subsequently, a second part of the drift region 106 may be grown 620 over the first part of the drift region 610 for a second period of time. The step of growing 620 the second part comprises changing a concentration of dopants over the second period of time with a second rate, the second rate being greater than the first rate. For example, the second part of the drift region 106 may be grown using an epitaxial growth process with the concentration of dopants present during the epitaxial growth process changing (such as decreasing) over the second period of time with the second rate. In some embodiments the second rate may be the same over the second period of time.

Subsequently, at least one trench 110 is formed 630 in the semiconductor body 102. The at least one trench 110 extending from the first major surface 101 into the semiconductor body 102 along a first direction z.

Then, the method 600 continues with forming 640 a field dielectric 126 in the trench 110. The thickness t of the field dielectric 124 may increase along the first direction z from a first thickness t₁ at a first distance d₁ from the first major surface 101 to a second thickness t₂ at a second distance d₂ from the first major surface 101, as discussed above with regard to FIGS. 1A-1C, 2A-2C, 3 and 4A-4C. The first distance d₁ may be adjacent to the second part of the drift region 106 (grown in step 620) and the second distance d₂ may be adjacent to the first part of the drift region 106 (grown in step 610). In some embodiments, a difference d between the second distance d₂ and the first distance d₁ along the first direction z is at most 20% of a total height h_{fp} of the field electrode 124, and the second thickness t₂ is at least 1.1 times the first thickness t₁. In other examples, a difference d between the second distance d₂ and the first distance d₁ along the first direction z is at most 15% of a total height h_{fp} of the field electrode 124, and the second thickness t₂ is at least 1.2 times the first thickness t₁. In yet other examples, a difference d between the second distance d₂ and the first distance d₁ along the first direction z is at most 10% of a total height h_{fp} of the field electrode 124, and the second thickness t₂ is at least 1.15 times the first thickness t₁.

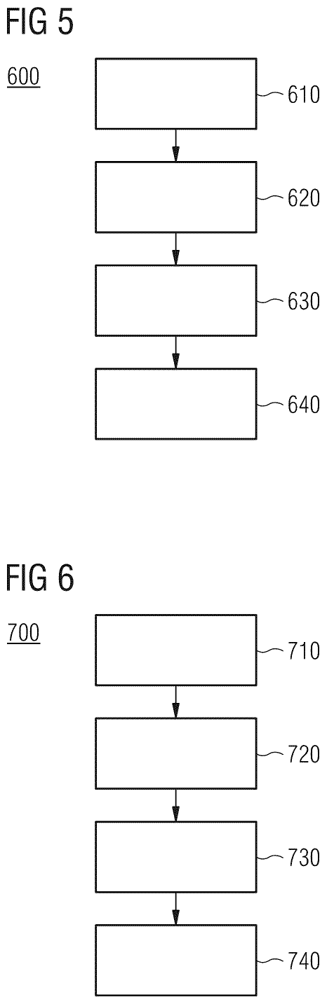

FIG. 6 illustrates another embodiment of producing the semiconductor devices 100, 200, 300, 400, 500 illustrated in illustrated in FIGS. 1A-1C, 2A-2C, 3, and 4A-4C. According to this embodiment, dopants are implanted 710 into a first part of a drift region 106 of a semiconductor body 102 such that a doping profile in the first part of the drift region 106 comprises at least one first slope (such as s₂). For example, implanting 710 could comprise implanting dopants into the first part of drift region 106 using a first implantation energy (e.g., a first implantation energy that is sufficiently high to reach into a deeper part of the drift region 106). As an alternative, implanting 710 could be performed after only a first part of the drift region 106 has been grown (e.g., via epitaxial growth) and a remainder of drift region 106 could be grown after the implanting step 710 is performed.

Subsequently, dopants are implanted 720 into a second part of the drift region 106 positioned over the first part of the drift region 106 such that a doping profile in the second part of the drift region 106 comprises at least one second slope (such as s₁), wherein the at least one first slope is smaller than the at least one second slope. For example, implanting 720 could comprise implanting dopants into the second part of drift region 106 using a second implantation energy that is lower than the first implantation energy used for implanting 710 dopants into the first part of the drift region (e.g., a second implantation energy that is high enough to reach the second part of drift region 106 but sufficiently low so as to not reach into the first part of drift region 106). As an alternative, implanting 720 could be performed after the second part of the drift region 106 has been grown (e.g., via epitaxial growth) and a remainder of semiconductor body 102 could be grown after the implanting step 720 is performed.

Subsequently, at least one trench 110 is formed 730 in the semiconductor body 102. The at least one trench 110 extending from the first major surface 101 into the semiconductor body 102 along a first direction z.

Then, the method 700 continues with forming 740 a field dielectric 126 in the trench 110. The thickness t of the field dielectric 124 may increase along the first direction z from a first thickness t₁ at a first distance d₁ from the first major surface 101 to a second thickness t₂ at a second distance d₂ from the first major surface 101, as discussed above with regard to FIGS. 1A-1C, 2A-2C, 3 and 4A-4C. The first distance d₁ may be adjacent to the second part of the drift region 106 (where dopants were implanted in step 720) and the second distance d₂ may be adjacent to the first part of the drift region 106 (where dopants were implanted in step 710). In some embodiments, a difference d between the second distance d₂ and the first distance d₁ along the first direction z is at most 20% of a total height h_{fp} of the field electrode 124, and the second thickness t₂ is at least 1.1 times the first thickness t₁. In other examples, a difference d between the second distance d₂ and the first distance d₁ along the first direction z is at most 15% of a total height h_{fp} of the field electrode 124, and the second thickness t₂ is at least 1.2 times the first thickness t₁. In yet other examples, a difference d between the second distance d₂ and the first distance d₁ along the first direction z is at most 10% of a total height h_{fp} of the field electrode 124, and the second thickness t₂ is at least 1.15 times the first thickness t₁.

Although the present disclosure is not so limited, the following numbered examples demonstrate one or more aspects of the disclosure.

Example 1: A semiconductor device, comprising: semiconductor body having a first major surface; and a trench formed in the semiconductor body, the trench extending from the first major surface into the semiconductor body along a first direction, wherein the trench comprises a field electrode and a field dielectric positioned between the field electrode and the semiconductor body, wherein a thickness of the field dielectric increases along the first direction from a first thickness at a first distance from the first major surface to a second thickness at a second distance from the first major surface, wherein a difference between the second distance and the first distance along the first direction is at most 20% of a total height of the field electrode, wherein the second thickness is at least 1.1 times the first thickness, wherein the semiconductor body comprises a drift region, wherein the drift region comprises a doping profile along the first direction, wherein a slope of the doping profile changes along the first direction between the first distance and the second distance from the first major surface

Example 2: The semiconductor device of Example 1, wherein a difference between the second distance and the first distance along the first direction is at most 15% of a total height of the field electrode, wherein the second thickness is at least 1.2 times the first thickness.

Example 3: The semiconductor device of Example 1, wherein a difference between the second distance and the first distance along the first direction is at most 10% of a total height of the field electrode, wherein the second thickness is at least 1.15 times the first thickness.

Example 4: The semiconductor device of Example 1, wherein the trench comprises an upper region, a lower region and an intermediate region positioned between the upper region and the lower region, wherein the intermediate region is positioned between the first distance and the second distance, and wherein the field electrode extends from the upper region into the lower region of the trench.

Example 5: The semiconductor device of Example 4, wherein a ratio of the second thickness of the field dielectric over the first thickness of the field dielectric is in a range between 1.5 and 2.5, and wherein a height of the field electrode in the upper region is between 0.75 times and 1.25 times a height of the field electrode in the lower region.

Example 6: The semiconductor device of Example 4, wherein along the first direction, a height of the field electrode in the upper region is more than 10% of the total height of the field electrode, and wherein along the first direction, a height of the field electrode in the lower region is more than 10% of the total height of the field electrode.

Example 7: The semiconductor device of Example 5, wherein along the first direction, a height of the field electrode in the upper region is more than 25% of the total height of the field electrode, and wherein along the first direction, a height of the field electrode in the lower region is more than 25% of the total height of the field electrode.

Example 8: The semiconductor device of any of Examples 1 to 7, wherein the trench is elongated along a second direction, and wherein the trench further comprises a gate electrode positioned above the field electrode.

Example 9: The semiconductor device of any of Examples 1 to 8, wherein a thickness of the field electrode decreases along the first direction from a first thickness of the field electrode at the first distance to a second thickness of the field electrode at the second distance.

Example 10: The semiconductor device of any of Examples 1 to 8, wherein a thickness of the field electrode increases or remains the same along the first direction from a first thickness of the field electrode at the first distance to a second thickness of the field electrode at the second distance.

Example 11: The semiconductor device of any of Examples 1 to 7, wherein the trench has a columnar shape, and wherein a thickness of the field electrode decreases along the first direction from a first thickness of the field electrode at the first distance to a second thickness of the field electrode at the second distance.

Example 12: The semiconductor device of any of Examples 1 to 7, wherein the trench has a columnar shape, and wherein a thickness of the field electrode increases or remains the same along the first direction from a first thickness of the field electrode at the first distance to a second thickness of the field electrode at the second distance.

Example 13: The semiconductor device of any of Examples 1 to 12, wherein the slope of the doping profile changes between the first distance and the second distance approximately proportional to a ratio between the first thickness of the field dielectric over the second thickness of the field dielectric.

Example 14: The semiconductor device of any of Examples 1 to 13, wherein a thickness of the field dielectric increases along the first direction from a third thickness at a third distance from the first major surface to a fourth thickness at a fourth distance from the first major surface, wherein a difference between the fourth distance and the third distance along the first direction is at most 20% of the total height of the field electrode, wherein the fourth thickness is at least 1.1 times the third thickness, wherein a slope of the doping profile changes along the first direction between the third distance and the fourth distance from the first major surface.

Example 15: The semiconductor device of Example 14, wherein the slope of the doping profile changes between the third distance and the fourth distance approximately proportional to a ratio between the third thickness of the field dielectric over the fourth thickness of the field dielectric.

Example 16: A method for fabricating a semiconductor device having a semiconductor body with a first major surface, the method comprising: growing a first part of a drift region of the semiconductor body over a substrate of the semiconductor body for a first period of time, wherein growing the first part comprises changing a concentration of dopants over the first period of time with a first rate; growing a second part of the drift region of the semiconductor body over the first part of the drift region for a second period of time, wherein growing the second part comprises changing a concentration of dopants over the second period of time with a second rate, the second rate being greater than the first rate; forming a trench in the semiconductor body, the trench extending from the first major surface into the semiconductor body along a first direction; and forming a field dielectric in the trench, wherein a thickness of the field dielectric increases along the first direction from a first thickness at a first distance from the first major surface to a second thickness at a second distance from the first major surface, wherein the first distance is adjacent to the second part of the drift region, and wherein the second distance is adjacent to the first part of the drift region, wherein the second thickness is at least 1.1 times the first thickness.

Example 17: A method for fabricating a transistor device having a semiconductor body with a first major surface, the method comprising: implanting dopants into a first part of a drift region of the semiconductor body such that a doping profile in the first part of the drift region comprises at least one first slope; implanting dopants into a second part of the drift region positioned over the first part of the drift region such that a doping profile in the second part of the drift region comprises at least one second slope, wherein the at least one first slope is smaller than the at least one second slope; forming a trench in the semiconductor body, the trench extending from the first major surface into the semiconductor body along a first direction; and forming a field dielectric in the trench, wherein a thickness of the field dielectric increases along the first direction from a first thickness at a first distance from the first major surface to a second thickness at a second distance from the first major surface, wherein the first distance is adjacent to the second part of the drift region, and wherein the second distance is adjacent to the first part of the drift region, wherein the second thickness is at least 1.1 times the first thickness.

Example 18: A semiconductor device, comprising: a semiconductor body having a first major surface; and a trench formed in the semiconductor body, the trench extending from the first major surface into the semiconductor body along a first direction, wherein the trench comprises a field electrode and a field dielectric positioned between the field electrode and the semiconductor body, wherein the field dielectric comprises a first thickness over a first height h₁ of the field electrode and a second thickness over a second height h₂ of the field electrode, and wherein the field electrode comprises a total height h_{fp}, wherein 0.1<h₁/h_{fp}<0.8, 0.1<h₂/h_{fp}<0.8, and (h₁+h₂)/h_{fp}<0.9, wherein the semiconductor body comprises a drift region, wherein the drift region comprises a doping profile along the first direction, wherein a slope of the doping profile changes along the first direction between the first distance and the second distance from the first major surface.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A semiconductor device, comprising:
a semiconductor body having a first major surface; and
a trench formed in the semiconductor body, the trench extending from the first major surface into the semiconductor body along a first direction,
wherein the trench comprises a field electrode and a field dielectric positioned between the field electrode and the semiconductor body,
wherein a thickness of the field dielectric increases along the first direction from a first thickness at a first distance from the first major surface to a second thickness at a second distance from the first major surface,
wherein a difference between the second distance and the first distance along the first direction is at most 20% of a total height of the field electrode,
wherein the second thickness is at least 1.1 times the first thickness,
wherein the semiconductor body comprises a drift region having a doping profile along the first direction,
wherein a slope of the doping profile changes along the first direction between the first distance and the second distance from the first major surface.

2. The semiconductor device of claim 1,
wherein a difference between the second distance and the first distance along the first direction is at most 15% of the total height of the field electrode,
wherein the second thickness is at least 1.2 times the first thickness.

3. The semiconductor device of claim 1,
wherein a difference between the second distance and the first distance along the first direction is at most 10% of the total height of the field electrode,
wherein the second thickness is at least 1.15 times the first thickness.

4. The semiconductor device of claim 1,
wherein the trench comprises an upper region, a lower region, and an intermediate region positioned between the upper region and the lower region,
wherein the intermediate region is positioned between the first distance and the second distance, and
wherein the field electrode extends from the upper region into the lower region.

5. The semiconductor device of claim 4,
wherein a ratio of the second thickness of the field dielectric over the first thickness of the field dielectric is in a range between 1.5 and 2.5, and
wherein a height of the field electrode in the upper region is between 0.75 times and 1.25 times a height of the field electrode in the lower region.

6. The semiconductor device of claim 5,
wherein along the first direction, a height of the field electrode in the upper region is more than 25% of the total height of the field electrode, and
wherein along the first direction, a height of the field electrode in the lower region is more than 25% of the total height of the field electrode.

7. The semiconductor device of claim 4,
wherein along the first direction, a height of the field electrode in the upper region is more than 10% of the total height of the field electrode, and
wherein along the first direction, a height of the field electrode in the lower region is more than 10% of the total height of the field electrode.

8. The semiconductor device of claim 1,
wherein the trench is elongated along a second direction, and
wherein the trench further comprises a gate electrode positioned above the field electrode.

9. The semiconductor device of claim 1,
wherein a thickness of the field electrode decreases along the first direction from a first thickness of the field electrode at the first distance to a second thickness of the field electrode at the second distance.

10. The semiconductor device of claim 1,
wherein a thickness of the field electrode increases or remains the same along the first direction from a first thickness of the field electrode at the first distance to a second thickness of the field electrode at the second distance.

11. The semiconductor device of claim 1,
wherein the trench has a columnar shape, and
wherein a thickness of the field electrode decreases along the first direction from a first thickness of the field electrode at the first distance to a second thickness of the field electrode at the second distance.

12. The semiconductor device of claim 1,
wherein the trench has a columnar shape, and
wherein a thickness of the field electrode increases or remains the same along the first direction from a first thickness of the field electrode at the first distance to a second thickness of the field electrode at the second distance.

13. The semiconductor device of claim 1,
wherein between the first distance and the second distance, the slope of the doping profile changes approximately proportional to a ratio between the first thickness of the field dielectric over the second thickness of the field dielectric.

14. The semiconductor device of claim 1,
wherein a thickness of the field dielectric increases along the first direction from a third thickness at a third distance from the first major surface to a fourth thickness at a fourth distance from the first major surface,
wherein a difference between the fourth distance and the third distance along the first direction is at most 20% of the total height of the field electrode,
wherein the fourth thickness is at least 1.1 times the third thickness,
wherein the slope of the doping profile changes along the first direction between the third distance and the fourth distance from the first major surface.

15. The semiconductor device of claim 14,
wherein between the third distance and the fourth distance, the slope of the doping profile changes approximately proportional to a ratio between the third thickness of the field dielectric over the fourth thickness of the field dielectric.

16. A method for fabricating a semiconductor device having a semiconductor body with a first major surface, the method comprising:
growing a first part of a drift region of the semiconductor body over a substrate of the semiconductor body for a first period of time, wherein growing the first part comprises changing a concentration of dopants over the first period of time with a first rate;
growing a second part of the drift region of the semiconductor body over the first part of the drift region for a second period of time, wherein growing the second part comprises changing a concentration of dopants over the second period of time with a second rate, the second rate being greater than the first rate;
forming a trench in the semiconductor body, the trench extending from the first major surface into the semiconductor body along a first direction; and
forming a field dielectric in the trench, wherein a thickness of the field dielectric increases along the first direction from a first thickness at a first distance from the first major surface to a second thickness at a second distance from the first major surface, wherein the first distance is adjacent to the second part of the drift region, wherein the second distance is adjacent to the first part of the drift region, and wherein the second thickness is at least 1.1 times the first thickness.

17. A method for fabricating a transistor device having a semiconductor body with a first major surface, the method comprising:
implanting dopants into a first part of a drift region of the semiconductor body such that a doping profile in the first part of the drift region comprises at least one first slope;
implanting dopants into a second part of the drift region positioned over the first part of the drift region such that a doping profile in the second part of the drift region comprises at least one second slope, wherein the at least one first slope is smaller than the at least one second slope;
forming a trench in the semiconductor body, the trench extending from the first major surface into the semiconductor body along a first direction; and
forming a field dielectric in the trench, wherein a thickness of the field dielectric increases along the first direction from a first thickness at a first distance from the first major surface to a second thickness at a second distance from the first major surface, wherein the first distance is adjacent to the second part of the drift region, wherein the second distance is adjacent to the first part of the drift region, and wherein the second thickness is at least 1.1 times the first thickness.

18. A semiconductor device, comprising:
a semiconductor body having a first major surface; and
a trench formed in the semiconductor body, the trench extending from the first major surface into the semiconductor body along a first direction,
wherein the trench comprises a field electrode and a field dielectric positioned between the field electrode and the semiconductor body,
wherein the field dielectric comprises a first thickness over a first height h₁ of the field electrode and a second thickness over a second height h₂ of the field electrode,
wherein the field electrode comprises a total height h_{fp},
wherein 0.1<h₁/h_{fp}<0.8, 0.1<h₂/h_{fp}<0.8, and (h₁+h₂)/h_{fp}<0.9,
wherein the semiconductor body comprises a drift region having a doping profile along the first direction,
wherein a slope of the doping profile changes along the first direction between the first distance and the second distance from the first major surface.
